(19) United States
(12) Patent Application Publication
(10) Pub. No.: US 2023/0378072 A1
(43) Pub. Date: Nov. 23, 2023

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shuai-Lin Liu, Taichung City (TW); Nai-Hao Kao, Taichung City (TW); Chao-Chiang Pu, Taichung City (TW); Yi-Min Fu, Taichung City (TW); Yu-Po Wang, Taichung City (TW)

(73) Assignee: SILICONWARE PRECISION INDUSTRIES CO., LTD., Taichung City (TW)

(21) Appl. No.: 17/857,887

(22) Filed: Jul. 5, 2022

(30) Foreign Application Priority Data
May 19, 2022 (TW) 111118703

(51) Int. Cl. H01L 23/538; H01L 25/065; H01L 23/498; H01L 21/48; H01L 21/56

(52) U.S. Cl. CPC H01L 23/5381; H01L 25/0655; H01L 23/5385; H01L 23/5386; H01L 23/49816; H01L 21/4853; H01L 21/486; H01L 21/565; H01L 23/49838; H01L 23/49822; H01L 21/4857; H01L 24/16

(57) ABSTRACT

An electronic package is provided, in which a plurality of electronic elements are disposed on a plurality of carrier structures, and at least one bridging element is disposed between at least two of the carrier structures to electrically bridge the two carrier structures. Therefore, when there is a need to increase the function of the electronic package, only one electronic element is arranged on a single carrier structure, and there is no need to increase the panel area of the carrier structure, so as to facilitate the control of the panel area of the carrier structure and avoid warpage of the carrier structure due to the oversized panel.

### BACKGROUND

### 1. Technical Field

The present disclosure relates to a semiconductor device, in particular, to an electronic package with a bridge element and manufacturing method thereof.

### 2. Description of Related Art

There are many technologies currently used in the field of chip packaging, such as Chip Scale Package (CSP), Direct Chip Attached (DCA), or Multi-Chip Module (MCM), and other flip-chip packaging modules, or chip stacking technology such as integrating the three-dimensional stacking of chips into a three-dimensional integrated circuit (3D IC), etc.

FIG. 1 is a schematic cross-sectional view of a conventional semiconductor package 1 for 3D IC chip stacking. As shown in FIG. 1, the manufacturing method of the semiconductor package 1 firstly provides a silicon interposer (through-silicon interposer, [TSI]) 10, the silicon interposer 10 has a chip-mounting side 10a and a transfer side 10b opposite to the chip-mounting side 10a and a plurality of conductive through-silicon vias (TSVs) 100 communicating the chip-mounting side 10a and the transfer side 10b, and the chip-mounting side 10a has a redistribution layer (RDL) 12 electrically connected to the conductive through-silicon vias 100; then, a semiconductor chip 11 is electrically bonded onto the redistribution layer 12 by a plurality of solder bumps 111 with electrode pads 110 of the semiconductor chip 11, and an underfill 112 is filled between the semiconductor chip 11 and the silicon interposer 10 to cover the solder bumps 111, and an encapsulant 14 is formed on the silicon interposer 10 to cover the semiconductor chip 11 and the underfill 112; afterwards, a packaging substrate 16 is electrically bonded onto the conductive through-silicon vias 100 with solder pads 160 thereof by a plurality of conductive elements 15 such as solder bumps or copper pillars, and another underfill 17 is filled between the silicon interposer 10 and the packaging substrate 16 to cover the conductive elements 15; finally, a plurality of solder balls 19 are connected to the bottom side of the packaging substrate 16 to connect to a circuit board (not shown).

In the conventional semiconductor package 1, usually only one semiconductor chip 11 is disposed on the single silicon interposer 10.

However, if there is a need to increase the function, a plurality of semiconductor chips 11 will need to be arranged on the single silicon interposer 10, and the area of the chip-mounting side 10a of the silicon interposer 10 needs to be increased, so that an area of a panel A of the silicon interposer 10 needs to be increased. As the area increases, warpage is likely to occur, which would result in poor contact or even cracking of the semiconductor chips 11 or the conductive elements 15, thereby causing problems such as poor yield and poor reliability of the semiconductor package 1.

Furthermore, if the area of the panel A of the silicon interposer 10 is increased, a greater stress will also be generated in the silicon interposer 10, so that the silicon interposer 10 is prone to cracking due to stress concentration.

In addition, if the area of the chip-mounting side 10a of the silicon interposer 10 is not increased, then the number of layers of the redistribution layer 12 needs to be increased, which not only increases the overall thickness of the semiconductor package 1, but also cannot meet the requirements of thinning, and because the more routing layers (e.g., wiring layers), the lower the process yield, so that the semiconductor chip 11 cannot be electrically connected to the redistribution layer 12 effectively, resulting in problems such as poor yield and poor reliability of the semiconductor package 1.

Therefore, there is a need for a solution that addresses the aforementioned shortcomings of the prior art.

### SUMMARY

In view of the aforementioned shortcomings of the prior art, the present disclosure provides an electronic package, which comprises: a plurality of carrier structures; a plurality of electronic elements, wherein each of the electronic elements is disposed on and electrically connected to each of the carrier structures; and a bridging element disposed between at least two of the plurality of carrier structures to electrically bridge the at least two of the plurality of carrier structures.

The present disclosure further provides a method of manufacturing an electronic package, which comprises: providing a plurality of carrier structures; disposing a plurality of electronic elements on the plurality of carrier structures respectively, wherein each of the electronic elements is electrically connected to each of the carrier structures; and disposing a bridging element between at least two of the plurality of carrier structures, wherein the bridging element electrically bridges the at least two of the plurality of carrier structures.

In the aforementioned electronic package and method, each of the carrier structures has a first side, a second side opposing to the first side, and a plurality of conductive vias connecting the first side and the second side, wherein the plurality of conductive vias are electrically connected to the plurality of electronic elements and the bridging element.

In the aforementioned electronic package and method, each of the carrier structures is formed with a circuit structure, wherein a plurality of the circuit structures of the plurality of carrier structures are electrically connected to the plurality of electronic elements and the bridging element.

In the aforementioned electronic package and method, a separation space is formed between adjacent two of the plurality of carrier structures, such that the bridging element spans the separation space and is electrically connected between the adjacent two of the plurality of carrier structures.

In the aforementioned electronic package and method, the bridging element is a semiconductor chip, wherein the bridging element is disposed between the at least two of the plurality of carrier structures via a plurality of conductive bumps and is electrically connected to the at least two of the plurality of carrier structures.

In the aforementioned electronic package and method, the present disclosure further comprises covering the plurality of carrier structures, the plurality of electronic elements and the bridging element by a packaging layer. For example, the packaging layer has a first surface and a second surface opposing to the first surface, wherein at least part of the plurality of electronic elements are exposed from the first surface. Alternatively, the packaging layer has a first surface and a second surface opposing to the first surface, wherein at least part of the plurality of carrier structures are exposed from the second surface.

In the aforementioned electronic package and method, the present disclosure further comprises disposing the plurality of carrier structures on a substrate structure, wherein the substrate structure is electrically connected to the plurality of carrier structures. For example, the plurality of carrier structures are disposed on the substrate structure via a plurality of conductive elements.

As can be understood from the above, in the electronic package and the manufacturing method thereof according the present disclosure, at least two carrier structures are electrically bridged by the bridging element, so that when there is a need to increase the function of the electronic package, only one electronic element is arranged on a single carrier structure, and there is no need to increase an area of a panel of each of the carrier structures. Therefore, compared with the prior art, the present disclosure can control the area of the panel of each of the carrier structures to avoid the warpage of the carrier structures, such that the electronic element or the conductive elements can be effectively electrically connected to each of the carrier structures to improve the yield and reliability of the electronic package.

Furthermore, if the conventional method increases the number of semiconductor chips by increasing the area of the panel of the silicon interposer, compared with the stress generated on a single large-area silicon interposer in the prior art, the stress generated on each of the carrier structures of the present disclosure is relatively small, so the carrier structures of the present disclosure can avoid the problem of cracking caused by stress concentration.

Also, since the plurality of carrier structures are electrically communicated by the bridging element, the plurality of carrier structures bridged by the bridging element can be served as the same carrier element. Therefore, compared with the prior art, each of the circuit structures of the present disclosure does not need to increase the number of layers of the redistribution layer, which not only reduces the overall thickness of the electronic package to meet the requirements of thinning, but also improves the process yield due to the redistribution layer can control the number of layers as required, so that each of the electronic elements can be effectively electrically connected to the redistribution layer to improve the yield and reliability of the electronic package.

### BRIEF DESCRIPTION OF THE DRAWINGS

FIG. 1 is a schematic cross-sectional view of a conventional semiconductor package.

FIG. 2A to FIG. 2E are schematic cross-sectional views illustrating a method of manufacturing an electronic package according to the present disclosure.

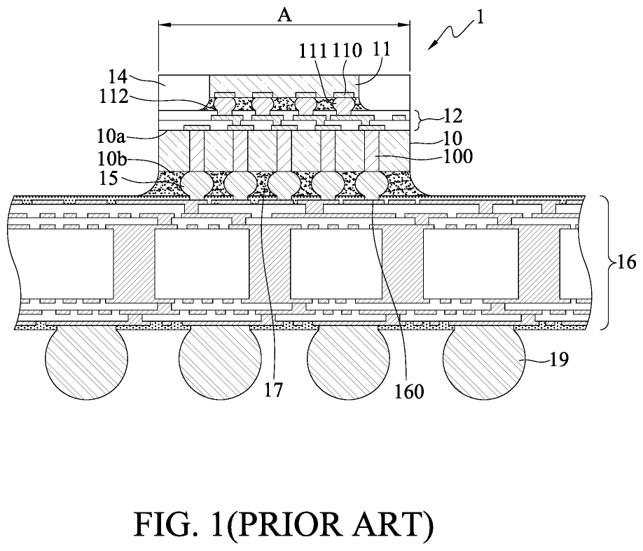

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios or sizes are construed as fall within the scope covered by the technical contents disclosed herein. Meanwhile, terms such as “above,” “first,” “second,” “one,” “a,” “an,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

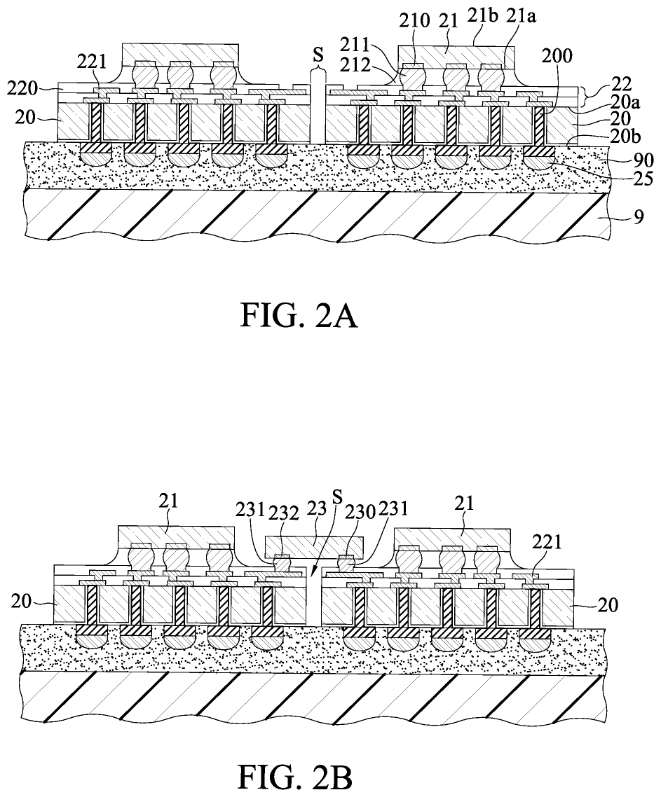

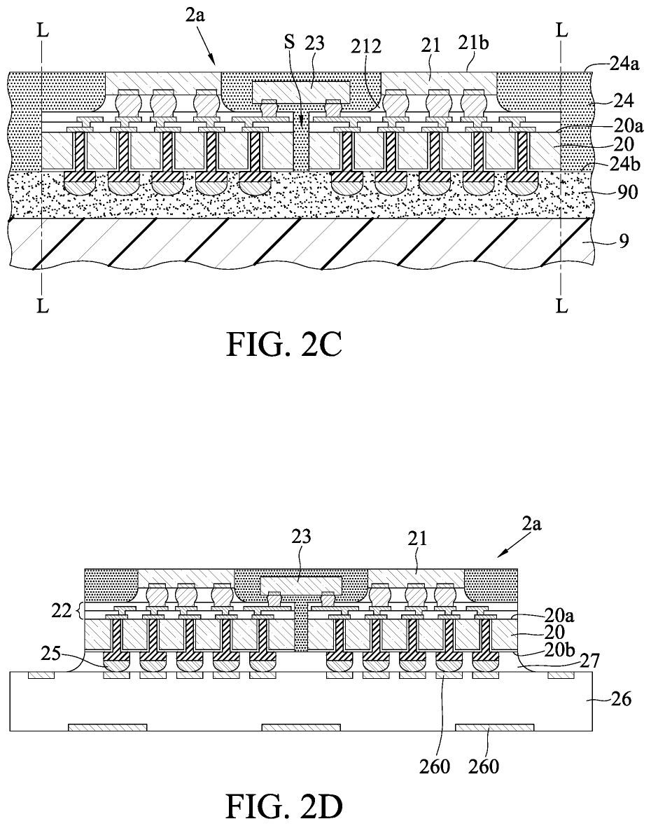

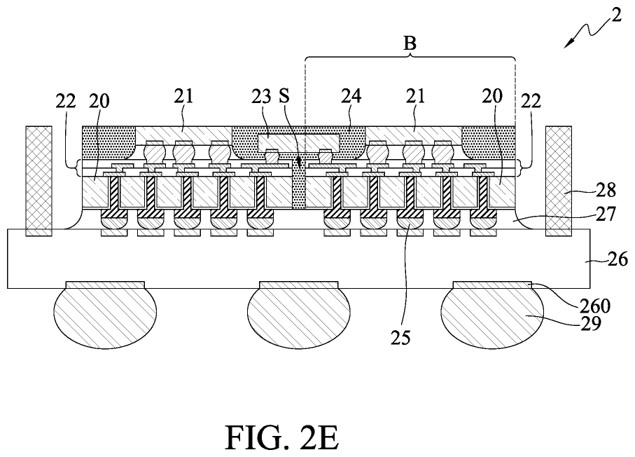

FIG. 2A to FIG. 2E are schematic cross-sectional views illustrating a method of manufacturing an electronic package 2 according to the present disclosure.

As shown in FIG. 2A, a plurality of spaced-apart carrier structures 20 are arranged on a carrier board 9 of a panel specification or a wafer level specification, and then at least one electronic element 21 is stacked on each of the carrier structures 20, wherein a separation space S is formed between each of the carrier structures 20.

The carrier board 9 is, for example, a board body made of semiconductor material (such as silicon or glass), on which an insulating bonding layer 90 is coated.

Each of the carrier structures 20 has a silicon-containing board body, such as a functional chip, a through-silicon interposer (TSI), or a glass substrate, and the board body is arranged with conductive lines.

In an embodiment, each of the carrier structures 20 is a through-silicon interposer and has a first side 20a and a second side 20b opposite to the first side 20a, and a plurality of conductive vias 200 connecting the first side 20a and the second side 20b for using as conductive lines, wherein the conductive vias 200 are conductive through-silicon vias (TSVs), and each of the conductive vias 200 is composed of a copper pillar and an insulating material surrounding the copper pillar. The manufacturing method of the conductive vias 200 is not limited to the above, and will not be detailed herein.

Furthermore, the first side 20a of each of the carrier structures 20 can be used as a chip-mounting side for disposing the electronic element 21, and the second side 20b of each of the carrier structures 20 can be used as a transfer side.

Also, a routing process can be selectively performed on the first side 20a of each of the carrier structures 20 to form a circuit structure 22 for using as a conductive circuit. For example, each of the circuit structures 22 comprises at least one dielectric layer 220 and a redistribution layer (RDL) 221 bonded to the dielectric layer 220, and the redistribution layer 221 is electrically connected to the plurality of conductive vias 200.

On the other hand, a plurality of conductive elements 25, such as conductive bumps, may be formed on the second side 20b of each of the carrier structures 20, so that each of the plurality of conductive elements 25 is bonded onto an end surface of each of the plurality of conductive vias 200 and embedded in the insulating bonding layer 90. For example, the plurality of conductive elements 25 comprise metal pillars (such as copper pillars) and/or solder material, and an Under Bump Metallurgy (UBM) layer may be formed between the plurality of conductive elements 25 and the plurality of conductive vias 200, wherein the structure and material of the UBM layer are various and not particularly limited, so they will not be detailed.

It should be understood that a circuit structure (not shown) can also be formed on the second side 20b of each of the carrier structures 20 so as to configure the plurality of conductive elements 25.

The electronic element 21 is disposed on the first side 20a of each of the carrier structures 20 and electrically connected to the plurality of conductive vias 200.

In an embodiment, each of the electronic elements 21 is an active element, a passive element, or a combination of the active element and the passive element, wherein the active element is for example a semiconductor chip, and the passive element is for example a resistor, a capacitor, or an inductor. For example, each of the electronic elements 21 has an active surface 21a and an inactive surface 21b opposite to the active surface 21a, and the active surface 21a has a plurality of electrode pads 210, so that the electrode pads 210 are disposed on each of the circuit structures 22 in a flip-chip manner via a plurality of conductive bumps 211 (such as solder material) and are electrically connected to the redistribution layer 221, and then the conductive bumps 211 are covered with an underfill 212.

As shown in FIG. 2B, at least one bridging element 23 is disposed on two adjacent carrier structures 20, so that the bridging element 23 spans the separation space S, and the bridging element 23 is electrically connected between the two adjacent carrier structures 20.

In an embodiment, the bridging element 23 is a semiconductor chip. The bridging element 23 is disposed on the circuit structures 22 in a flip-chip manner via a plurality of conductive bumps 231 (such as solder material) and is electrically connected to the redistribution layer 221.

Furthermore, electrode pads 230 on one side of the bridging element 23 are bonded to one of the carrier structures 20, and electrode pads 232 on the other side of the bridging element 23 are bonded to the other carrier structure 20, so that any two adjacent carrier structures 20 can be electrically connected with each other by the bridging element 23.

As shown in FIG. 2C, a packaging layer 24 is formed on the insulating bonding layer 90 (or on the first side 20a of each of the carrier structures 20 and in the separation space S), so that the packaging layer 24 covers the electronic elements 21, the underfill 212 and the bridging element 23 to form an electronic module 2a.

In an embodiment, the packaging layer 24 is an insulating material, such as polyimide (PI), dry film, encapsulant such as epoxy resin, or molding compound. For example, the packaging layer 24 can be formed on the insulating bonding layer 90 by liquid compound, injection, lamination, or compression molding.

Furthermore, the packaging layer 24 has a first surface 24a and a second surface 24b opposite to the first surface 24a, so that the packaging layer 24 is bonded to the insulating bonding layer 90 with the second surface 24b thereof, and the first surface 24a of the packaging layer 24 may be flush with the inactive surface 21b of each of the electronic elements 21 by a leveling process, so that the electronic elements 21 are exposed from the first surface 24a of the packaging layer 24. For example, the leveling process removes partial material of the packaging layer 24 by grinding.

As shown in FIG. 2D, a singulation process is performed along cutting paths L shown in FIG. 2C, and the carrier board 9 and the insulating bonding layer 90 thereon are removed to expose the second side 20b of each of the carrier structures 20 and the plurality of conductive elements 25, such that the electronic module 2a is disposed onto a substrate structure 26 by the plurality of conductive elements 25 thereof.

In an embodiment, the substrate structure 26 is, for example, a packaging substrate with a core layer or a coreless packaging substrate. The substrate structure 26 is configured with at least one routing layer 260, such that the plurality of conductive elements 25 are electrically connected to the routing layer 260.

Furthermore, an underfill 27 can be formed on the substrate structure 26, so that the underfill 27 can cover the plurality of conductive elements 25.

As shown in FIG. 2E, at least one heat sink 28 is disposed on the upper side of the substrate structure 26 (i.e., the side connected to the electronic module 2a), and a ball placement process can be performed on the routing layer 260 on the lower side of the substrate structure 26 so as to form a plurality of solder balls 29 for mounting on a circuit board (not shown).

Therefore, the method of the present disclosure uses the bridging element 23 to electrically bridge at least two carrier structures 20, so that when there is a need to increase the function of the electronic package 2, only one electronic element 21 is arranged on a single carrier structure 20, and there is no need to increase an area of a panel B of each of the carrier structures 20. Therefore, compared with the prior art, the manufacturing method of the present disclosure can control the area of the panel B of a single carrier structure 20 to avoid warpage of the carrier structures 20. As such, the electronic element 21 or the conductive elements 25 can be electrically connected to each of the carrier structures 20 effectively to improve the yield and reliability of the electronic package 2.

Furthermore, if the conventional method increases the number of semiconductor chips by increasing the area of the panel of the silicon interposer, compared with the stress generated on a single large-area silicon interposer in the prior art, the stress generated on each of the carrier structures 20 of the present disclosure is relatively small, so the carrier structures 20 of the present disclosure can avoid the problem of cracking caused by stress concentration.

Also, since the plurality of carrier structures 20 are electrically communicated by the bridge element 23, the plurality of carrier structures 20 bridged by the bridging element 23 can be served as the same carrier element. Therefore, compared with the prior art, each of the circuit structures 22 of the present disclosure does not need to increase the number of layers of the redistribution layer 221, which not only reduces the overall thickness of the electronic package 2 to meet the requirements of thinning, but also improves the process yield due to the redistribution layer 221 can control the number of layers as required, so that each of the electronic elements 21 can be effectively electrically connected to the redistribution layer 221 to improve the yield and reliability of the electronic package 2.

The present disclosure further provides an electronic package 2, which comprises: a plurality of carrier structures 20, a plurality of electronic elements 21, and at least one bridging element 23.

Each of the carrier structures 20 has a first side 20a and a second side 20b opposite to the first side 20a.

Each of the electronic elements 21 is respectively disposed on and electrically connected to each of the carrier structures 20.

The bridging element 23 is disposed on the adjacent two of the plurality of carrier structures 20 to electrically bridge the adjacent two of the plurality of carrier structures 20. In addition, in other embodiments, according to application requirements, a single bridging element 23 can also electrically bridge the three (or more than three) carrier structures 20.

In one embodiment, the plurality of carrier structures 20 have a plurality of conductive vias 200 connecting the first side 20a and the second side 20b, such that the plurality of conductive vias 200 are electrically connected to the plurality of electronic elements 21 and the bridging element 23.

In one embodiment, each of circuit structures 22 is formed on each of the carrier structures 20, so that the plurality of circuit structures 22 of the plurality of carrier structures 20 are electrically connected to the plurality of electronic elements 21 and the bridging element 23.

In one embodiment, a separation space S is formed between the adjacent two of the plurality of carrier structures 20, such that the bridging element 23 spans the separation space S and is electrically connected between the adjacent two of the plurality of carrier structures 20.

In one embodiment, the bridging element 23 is a semiconductor chip, which is disposed on the at least two adjacent carrier structures 20 via a plurality of conductive bumps 231 and is electrically connected to the two adjacent carrier structures 20.

In one embodiment, the electronic package 2 further comprises a packaging layer 24 for covering the plurality of carrier structures 20, the plurality of electronic elements 21 and the bridging element 23. For example, the packaging layer 24 has a first surface 24a and a second surface 24b opposite to the first surface 24a, so that at least part of the electronic elements 21 are exposed from the first surface 24a. Alternatively, at least part of the carrier structures 20 are exposed from the second side 20b.

In one embodiment, the electronic package 2 further comprises a substrate structure 26 for disposing the plurality of carrier structures 20, and the substrate structure 26 is electrically connected to the plurality of carrier structures 20. For example, the plurality of carrier structures 20 are disposed on the substrate structure 26 via a plurality of conductive elements 25.

In view of the above, in the electronic package and manufacturing method thereof according to the present disclosure, multiple carrier structures are electrically bridged by the bridging element, so that when there is a need to increase the function of the electronic package, only one electronic element is arranged on a single carrier structure, and there is no need to increase an area of a panel of each of the carrier structures. Therefore, the present disclosure can effectively avoid the warpage of the carrier structures, and can control the stress generated on each carrier structure, so as to avoid the problem of cracking caused by stress concentration.

Further, since multiple carrier structures are electrically communicated by the bridging element, the multiple carrier structures bridged by the bridging element can be served as the same carrier element. Therefore, each of the circuit structures of the present disclosure does not need to increase the number of layers of the redistribution layer, which not only reduces the overall thickness of the electronic package to meet the requirements of thinning, but also improves the process yield due to the redistribution layer can control the number of layers as required, so that each of the electronic elements can be effectively electrically connected to the redistribution layer to improve the yield and reliability of the electronic package.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a plurality of carrier structures;
a plurality of electronic elements, wherein each of the electronic elements is disposed on and electrically connected to each of the carrier structures; and
a bridging element disposed between at least two of the plurality of carrier structures to electrically bridge the at least two of the plurality of carrier structures.

2. The electronic package of claim 1, wherein each of the carrier structures has a first side, a second side opposing to the first side, and a plurality of conductive vias connecting the first side and the second side, and wherein the plurality of conductive vias are electrically connected to the plurality of electronic elements and the bridging element.

3. The electronic package of claim 1, wherein each of the carrier structures is formed with a circuit structure, and wherein a plurality of the circuit structures of the plurality of carrier structures are electrically connected to the plurality of electronic elements and the bridging element.

4. The electronic package of claim 1, wherein a separation space is formed between adjacent two of the plurality of carrier structures, such that the bridging element spans the separation space and is electrically connected between the adjacent two of the plurality of carrier structures.

5. The electronic package of claim 1, wherein the bridging element is a semiconductor chip, and wherein the bridging element is disposed between the at least two of the plurality of carrier structures via a plurality of conductive bumps and is electrically connected to the at least two of the plurality of carrier structures.

6. The electronic package of claim 1, further comprising a packaging layer covering the plurality of carrier structures, the plurality of electronic elements and the bridging element.

7. The electronic package of claim 6, wherein the packaging layer has a first surface and a second surface opposing to the first surface, and wherein at least part of the plurality of electronic elements are exposed from the first surface.

8. The electronic package of claim 6, wherein the packaging layer has a first surface and a second surface opposing to the first surface, and wherein at least part of the plurality of carrier structures are exposed from the second surface.

9. The electronic package of claim 1, further comprising a substrate structure for disposing the plurality of carrier structures, wherein the substrate structure is electrically connected to the plurality of carrier structures.

10. The electronic package of claim 9, wherein the plurality of carrier structures are disposed on the substrate structure via a plurality of conductive elements.

11. A method of manufacturing an electronic package, comprising:
providing a plurality of carrier structures;
disposing a plurality of electronic elements on the plurality of carrier structures respectively, wherein each of the electronic elements is electrically connected to each of the carrier structures; and
disposing a bridging element between at least two of the plurality of carrier structures, wherein the bridging element electrically bridges the at least two of the plurality of carrier structures.

12. The method of claim 11, wherein each of the carrier structures has a first side, a second side opposing to the first side, and a plurality of conductive vias connecting the first side and the second side, and wherein the plurality of conductive vias are electrically connected to the plurality of electronic elements and the bridging element.

13. The method of claim 11, wherein each of the carrier structures is formed with a circuit structure, and wherein a plurality of the circuit structures of the plurality of carrier structures are electrically connected to the plurality of electronic elements and the bridging element.

14. The method of claim 11, wherein a separation space is formed between adjacent two of the plurality of carrier structures, such that the bridging element spans the separation space and is electrically connected between the adjacent two of the plurality of carrier structures.

15. The method of claim 11, wherein the bridging element is a semiconductor chip, and wherein the bridging element is disposed between the at least two of the plurality of carrier structures via a plurality of conductive bumps and is electrically connected to the at least two of the plurality of carrier structures.

16. The method of claim 11, further comprising covering the plurality of carrier structures, the plurality of electronic elements and the bridging element by a packaging layer.

17. The method of claim 16, wherein the packaging layer has a first surface and a second surface opposing to the first surface, and wherein at least part of the plurality of electronic elements are exposed from the first surface.

18. The method of claim 16, wherein the packaging layer has a first surface and a second surface opposing to the first surface, and wherein at least part of the plurality of carrier structures are exposed from the second surface.

19. The method of claim 11, further comprising disposing the plurality of carrier structures on a substrate structure, wherein the substrate structure is electrically connected to the plurality of carrier structures.

20. The method of claim 19, wherein the plurality of carrier structures are disposed on the substrate structure via a plurality of conductive elements.
